(19) United States
(12) Patent Application Publication
(10) Pub. No.: US 2025/0386600 A1
(43) Pub. Date: Dec. 18, 2025

(54) ACTIVE QUENCHING AND RESET SCHEMES FOR SPAD PIXEL FOR LOW ENERGY PER PULSE (EPP) AND HIGH MAXIMUM COUNT RATE (MCR)

(71) Applicants: STMicroelectronics International N.V., Geneva (CH); Politecnico Di Milano, Milano (IT)

(72) Inventors: Mohammed AL-RAWHANI, Glasgow (GB); Davide BERRETTA, Caronno Pertusella (IT)

(73) Assignees: STMicroelectronics International N.V., Geneva (CH); Politecnico Di Milano, Milano (IT)

(21) Appl. No.: 18/746,331

(22) Filed: Jun. 18, 2024

(51) Int. Cl. H01L 31/107; G01J 1/44; H01L 27/144

(52) U.S. Cl. CPC H10F 30/225; G01J 1/44; H10F 39/103; G01J 2001/442; G01J 2001/4466

(57) ABSTRACT

Disclosed herein is a single photon avalanche diode (SPAD) pixel circuit, including a SPAD having an anode coupled to a negative voltage and a cathode and a cascode transistor having a drain coupled to the cathode of the SPAD, a gate controlled by a cascode control signal, and a source. A readout circuit is coupled to the source of the cascode transistor and configured to detect a voltage change at the source of the cascode transistor and generate a pulse indicating an occurrence of an avalanche event. An active quenching circuit is coupled to the cathode of the SPAD and configured to detect an onset of the avalanche event and pull the cathode of the SPAD to a negative voltage to quench the avalanche event.

### TECHNICAL FIELD

This disclosure relates to the field of single photon detection and, more particularly, to single photon avalanche diode (SPAD) pixel circuits that incorporate active quenching and active reset techniques to improve the performance and minimize the Energy Per Pulse (EPP), the energy dissipated during each avalanche phenomenon, in applications such as time-of-flight (ToF) ranging and light detection and ranging (LIDAR).

### BACKGROUND

Single photon avalanche diode (SPAD) photodetectors are based on a PN junction that is reverse biased at a voltage exceeding a breakdown voltage. When a photon-generated carrier (via the internal photoelectric effect) is injected into the depletion region of the PN junction, a self-sustaining avalanche is caused, and detection of this avalanche can be used to indicate detection of the photon that generated the carrier. After an avalanche event, the SPAD needs to be reset or recharged to its initial state to be ready for detecting the next photon. This process involves quenching the SPAD, which is to say that the carriers are flushed from the depletion region, and the reverse bias voltage is restored to its original level above the breakdown voltage.

Such SPADs are utilized in applications such as time of flight (ToF) ranging and light ranging and detection (LIDAR). These applications may utilize fully depleted SPADs due to their suitability for near infrared applications. A sample SPAD circuit is shown in FIG. 1A in which a fully depleted SPAD Sp has its cathode connected to a high voltage VHV and its anode connected to a pull down circuit, which here is a resistor R1 with a small resistance, high enough to quench the avalanche, to help ensure a short deadtime, with signal output being taken at the anode. The anode voltage over time in an ideal case is shown in FIG. 1B with the first spike in the generated output signal occurring at time t1, where a quick rise in the signal is followed by a steady decay. However, fully depleted SPADs suffer from a low quench efficiency, meaning that they suffer from an inability to fully flush charge carriers out of the depletion region. This may result in real world performance similar to the second spike occurring at time t2 as shown in FIG. 1B, where rather than a single peak, dual voltage peaks for the output signal are generated, widening the output pulse from the SPAD, and reducing the rate at which photodetection can be performed.

Therefore, passive quenching circuits, with a larger quenching resistor than in FIG. 1A (such as on the order of hundreds of kilo Ohms), have been designed to assist with quenching SPADs. One such circuit is shown in FIG. 1C, where a SPAD Sp has its cathode connected to the high voltage VHV, and its anode connected to ground through a large quench resistor R2, with the signal output being taken at the anode of the SPAD Sp. The inclusion of the large quench resistor R2 increases the recharge time in an attempt to ensure that no charge carriers remain in the depletion region after avalanche. Because of this, the subsequent spike looks like the t1 pulse of FIG. 1D and not the t2 pulse of FIG. 1B.

Another such circuit is shown in FIG. 1E, where a SPAD Sp has its cathode connected to the high voltage VHV through large quench resistor R2, and its anode connected to ground, with the signal output being taken at the cathode of the SPAD Sp. As can be seen in FIG. 1F, here the inclusion of the large quench resistor R2 also increases the recharge time in an attempt to ensure that no charge carriers remain in the depletion region after avalanche.

While passive quenching circuits with properly designed quenching resistance can be effective in quenching the SPAD, they have several limitations. These include a lack of control over the reset time, a higher afterpulsing probability due to the total charge dissipated during the avalanche flowing through the SPAD, the risk of a stacked front-end at high photon rates if the SPAD is continuously retriggered before crossing back the front-end logic (leading to count losses), and variations in pulse amplitude that can worsen the timing resolution. To address these limitations, active quenching systems have been developed.

Active quenching involves using an electronic control circuit to rapidly reduce the reverse bias of the SPAD to below its breakdown voltage immediately after the detection of a photon. This halts the avalanche effect by quickly reducing the electric field in the depletion region, thus allowing the SPAD to return to a quiescent state faster than passive quenching would allow. The control circuitry monitors the output of the SPAD and, upon detection of the avalanche signal, it dynamically adjusts the voltage across the SPAD to quench the avalanche.

After the active quenching, an active reset circuit is used to forcibly remove any residual charge carriers from the depletion region after the avalanche has been quenched. This is typically achieved by keeping the SPAD off, in a hold-off time, at the breakdown voltage, using the active reset circuit. This process effectively removes any trapped charge that could otherwise lead to afterpulsing and prolong the dead time of the detector, or induce a fake event detection. The active reset ensures that the SPAD is rapidly returned to its initial state, ready for the next photon detection.

### SUMMARY

Disclosed herein is a single photon avalanche diode (SPAD) pixel circuit, including a SPAD having an anode coupled to a negative voltage and a cathode, and a cascode transistor having a drain coupled to the cathode of the SPAD, a gate controlled by a cascode control signal, and a source. A readout circuit is coupled to the source of the cascode transistor and is configured to detect a voltage change at the source of the cascode transistor and generate a pulse indicating an occurrence of an avalanche event. An active quenching circuit is coupled to the cathode of the SPAD and configured to detect an onset of the avalanche event and pull the cathode of the SPAD to a negative voltage to quench the avalanche event.

The cascode transistor may be an extended-drain PMOS transistor.

A passive quenching circuit may be coupled to the source of the cascode transistor, and the passive quenching circuit may include a PMOS transistor having a source coupled to a supply voltage, a drain coupled to the source of the cascode transistor, and a gate controlled by a quench control signal.

The readout circuit may include an inverter having an input coupled to the source of the cascode transistor and an output, and a delay circuit coupled to the output of the inverter and configured to extend a duration of the pulse.

The active quenching circuit may include a first NMOS transistor having a drain coupled to the cathode of the SPAD, a source and a body coupled to the negative voltage, and a gate, and a capacitor coupled between the gate of the first NMOS transistor and an output of the readout circuit.

The active quenching circuit may also include a second NMOS transistor having a drain coupled to the gate of the first NMOS transistor, and a source, a body, and a gate coupled to the negative voltage.

The SPAD may be a fully depleted three-dimensional SPAD.

The negative voltage may be lower than a reference voltage coupled to the readout circuit.

Also disclosed herein is a single photon avalanche diode (SPAD) pixel circuit, including a SPAD having an anode coupled to a negative voltage and a cathode, and a cascode transistor having a drain coupled to the cathode of the SPAD, a source coupled to an active reset circuit, and a gate controlled by a cascode control signal. A readout circuit is coupled to the source of the cascode transistor and is configured to detect a voltage change at the source of the cascode transistor and generate a digital pulse indicating an occurrence of an avalanche event. The active reset circuit is coupled to the source of the cascode transistor and configured to reset the SPAD after the avalanche event by pulling the source of the cascode transistor to a reference voltage.

The cascode transistor may be an extended-drain PMOS transistor. A passive quenching circuit may be coupled to the source of the cascode transistor, and the passive quenching circuit may include a PMOS transistor having a source coupled to a supply voltage, a drain coupled to the source of the cascode transistor, and a gate controlled by a quench control signal.

The active reset circuit may include an PMOS transistor having a drain coupled to the source of the cascode transistor, a source coupled to the reference voltage, and a gate controlled by a reset signal.

A delay generation circuit may be coupled to the readout circuit and configured to generate a delayed version of the digital pulse and provide the delayed version as the reset signal to the active reset circuit.

The delay generation circuit may include a series of inverters coupled between an output of the readout circuit and the reset signal, and a capacitor coupled between an output of a first inverter in the series of inverters and an input of a second inverter in the series of inverters.

The delay generation circuit may be controlled by an enable signal and its complement.

The readout circuit may include a first inverter having an input coupled to the source of the cascode transistor and an output, and a second inverter having an input coupled to the output of the first inverter and an output coupled to the delay generation circuit.

The second inverter may include a PMOS transistor and an NMOS transistor coupled in series between a supply voltage and a gated NMOS transistor, the gated NMOS transistor having a gate controlled by a control voltage.

The SPAD may be a fully depleted three-dimensional SPAD.

Also disclosed herein is a method of operating a single photon avalanche diode (SPAD) pixel. The method includes passively quenching an avalanche event in a SPAD by limiting current flow through the SPAD using a passive quenching circuit, actively quenching the avalanche event by pulling a cathode of the SPAD to a negative voltage using an active quenching circuit, detecting the avalanche event at the cathode of the SPAD using a readout circuit, and generating an output pulse with the readout circuit in response to detecting the avalanche event.

Detecting the avalanche event may include inverting a voltage change at the cathode of the SPAD using an inverter in the readout circuit, and generating a pulse at an output of the inverter in response to the voltage change. The method may further include extending a duration of the pulse using a delay circuit in the readout circuit, and using the extended pulse to control a transistor connected to the output of the inverter.

### BRIEF DESCRIPTION OF THE DRAWINGS

FIG. 1A is a schematic diagram of a conventional single photon avalanche diode (SPAD) circuit with a small quenching resistance, high enough to quench the avalanche.

FIG. 1B is a graph showing the anode voltage over time for the SPAD circuit of FIG. 1A.

FIG. 1C is a schematic diagram of a conventional SPAD circuit with a large quenching resistor connected between the anode and ground.

FIG. 1D is a graph showing the anode voltage over time for the SPAD circuit of FIG. 1C.

FIG. 1E is a schematic diagram of a conventional SPAD circuit with a large quenching resistor connected between the cathode and a high voltage.

FIG. 1F is a graph showing the cathode voltage over time for the SPAD circuit of FIG. 1E.

FIG. 2 is a schematic diagram of a SPAD pixel circuit incorporating active quenching functionality.

FIG. 2A is a detailed schematic diagram of the SPAD pixel circuit of FIG. 2.

FIG. 2B is a graph showing the voltage various nodes of the SPAD pixel circuit of FIG. 2A during an avalanche event.

FIG. 2C is a graph showing the voltage at the cathode of the SPAD in the SPAD pixel circuit of FIG. 2A during an avalanche event.

FIG. 2D is a graph showing the active quenching operation in the SPAD pixel circuit of FIG. 2A.

FIG. 3 is a schematic diagram of a SPAD pixel circuit incorporating active reset functionality.

FIG. 3A is a detailed schematic diagram of the SPAD pixel circuit of FIG. 3.

FIG. 3B is a graph showing the output pulse generated by the SPAD pixel circuit of FIG. 3A.

FIG. 3C is a timing diagram illustrating the operation of the SPAD pixel circuit of FIG. 3A.

FIG. 3D is a set of graphs showing the voltages at various nodes in the SPAD pixel circuit of FIG. 3A during an avalanche event and subsequent active reset.

FIG. 4 is a schematic diagram of a SPAD pixel circuit incorporating both active quenching and active reset.

FIG. 4A is a detailed schematic diagram of the SPAD pixel circuit of FIG. 4.

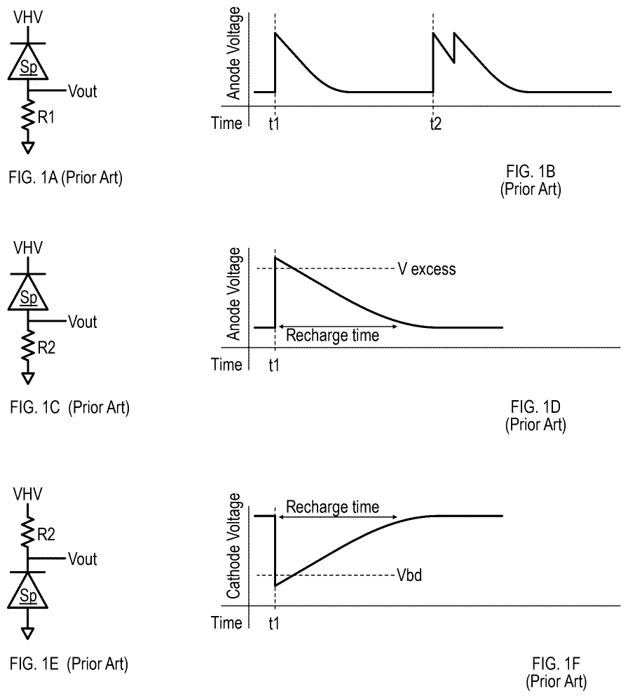

### DETAILED DESCRIPTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

Note that in the following description, any resistor or resistance mentioned is a discrete device, unless stated otherwise, and is not simply an electrical lead between two points. Therefore, any resistor or resistance connected between two points has a higher resistance than a lead between those two points, and such resistor or resistance cannot be interpreted as a lead. Similarly, any capacitor or capacitance mentioned is a discrete device, unless stated otherwise, and is not a parasitic element, unless stated otherwise. Additionally, any inductor or inductance mentioned is a discrete device, unless stated otherwise, and is not a parasitic element, unless stated otherwise.

### A. Active Quenching

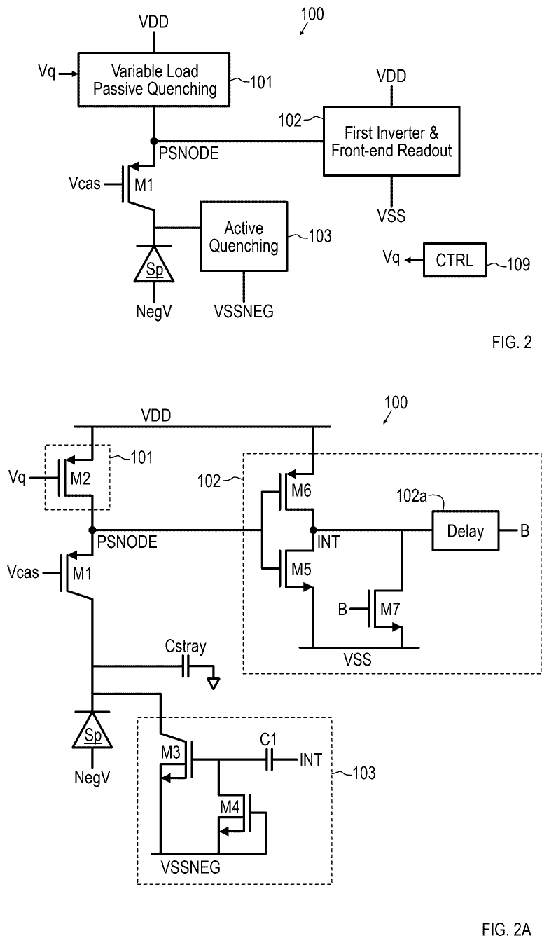

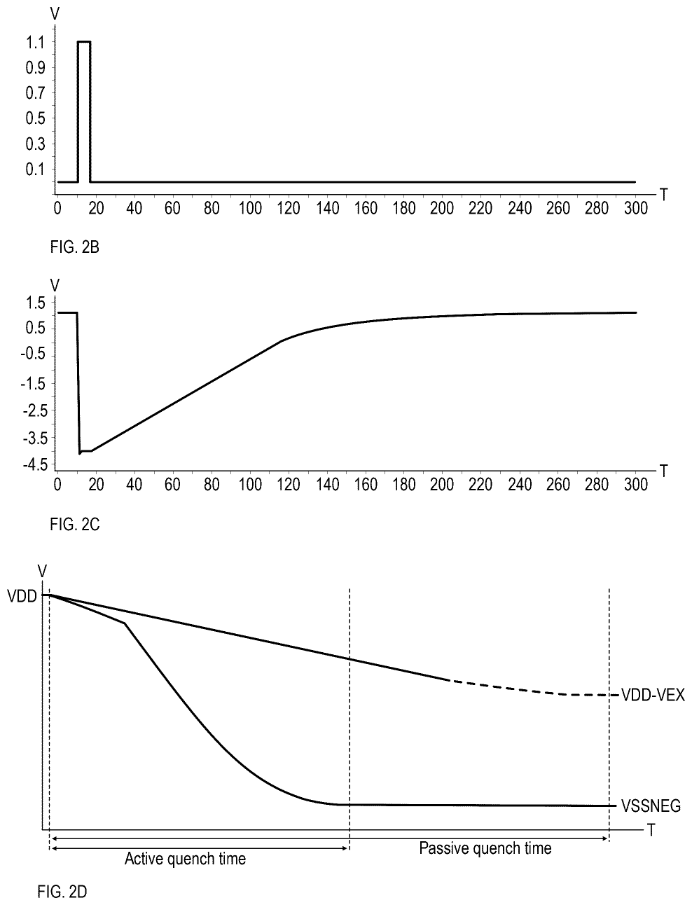

Now described with reference to FIG. 2 is a SPAD pixel 100, which includes a SPAD Sp, which may be a fully depleted three dimensional SPAD (e.g., a SPAD with a vertical structure and fully depleted absorption region), having its anode directly connected to a high negative voltage NegV, and having its cathode coupled to a supply voltage VDD through a cascode transistor M1 and a passive quenching circuit 101. The cathode of the SPAD Sp is read at a node labelled PSNODE at the source of the cascode transistor M1. The passive quenching circuit 101 serves to limit the current flow through the SPAD Sp during an avalanche event, helping to quench the avalanche and reset the SPAD for the next detection cycle. Readout circuitry 102, powered between the supply voltage VDD and a reference voltage VSS, performs this readout of node PSNODE. An active quenching circuit 103 is connected to the drain of cascode transistor M1 and performs active quenching of the SPAD Sp, utilizing a negative voltage VSSNEG. The active quenching circuit 103, in response to the onset of an avalanche event detected by the readout circuitry 102, actively pulls the SPAD cathode to a low voltage to rapidly quench the avalanche, reducing the SPAD quenching time and, therefore, the overall dead time.

Further details are shown in FIG. 2A. The cascode transistor M1, which is an extended-drain PMOS capable of handling a drain-to-source voltage of 5 to 7 volts or higher, has its drain connected to the cathode of SPAD Sp, its source connected to node PSNODE, and its gate controlled by a cascode control signal Vcas.

The passive quenching circuit 101 is formed by a PMOS transistor M2 having its source connected to the supply voltage VDD, its drain connected to PSNODE, and its gate controlled by a quench control signal Vq generated by control circuitry 109 or externally provided to control the quenching resistance.

The readout circuitry 102 includes an inverter formed by PMOS M6 and NMOS M5 series connected between the supply voltage VDD and the reference voltage VSS. The input of the inverter is connected to PSNODE, and the output of the inverter is connected to node INT. In greater detail, PMOS M6 has its source connected to the supply voltage VDD, its drain connected to node INT, and its gate controlled by the voltage at PSNODE. NMOS M5 has its drain connected to node INT, its source connected to the reference voltage VSS, and its gate controlled by the voltage at PSNODE. An NMOS transistor M7 has its drain connected to node INT, its source connected to the reference voltage VSS, and its gate controlled by the voltage at node B. A delay circuit 102a is connected to node INT and provides its output to node B.

A capacitor Cstray represents the stray capacitance associated with the cathode of SPAD Sp and is illustrated as being coupled between the cathode of SPAD Sp and ground.

The active quenching circuit 103 includes an extended-drain NMOS transistor M3 having its drain connected to the cathode of SPAD Sp, its source and body connected to the negative voltage VSSNEG, and its gate coupled through capacitor C1 to node INT. An NMOS transistor M4 has its drain connected to the gate of M3, and its source, body, and gate connected to the negative voltage VSSNEG.

When a photon is detected by the SPAD Sp, an avalanche event occurs, causing a sudden drop in the voltage at the SPAD cathode, as shown in FIG. 2C. This voltage drop is sensed at node INT, as shown in FIG. 2B, which is buffered by the cascode transistor M1. The passive quenching circuit 101 limits the current through the SPAD during the avalanche event, helping to quench the avalanche. The readout circuitry 102 detects the voltage change at PSNODE and generates a digital pulse at node INT, as shown in FIG. 2B, indicating the occurrence of an avalanche event. The delay circuit 102a extends the pulse duration at node INT by applying a delayed version of the pulse to the gate of transistor M7, which helps to maintain the pulse width at node INT for a predetermined duration.

The active quenching circuit 103 detects the onset of the avalanche through the coupling of node INT to the gate of transistor M3 via capacitor C1. As seen in FIG. 2D, firstly the passive quenching action starts discharging the cathode theoretically down to VDD-VEX, with VEX being an excess bias voltage applied to the SPAD. Secondarily, during the active quench time, M3 quickly pulls the SPAD cathode to the negative voltage VSSNEG, rapidly quenching the avalanche and reducing the quenching time compared to a passive-only solution. Transistor M4 acts as a weak pull-down network to prevent the gate of M3 from floating during the reset phase. After the active quench time, the passive reset phase begins, where the voltage at the SPAD cathode gradually rises back to VDD, as shown in FIG. 2C. This passive reset phase allows the SPAD to fully recover and prepare for the next detection event. Once the SPAD is reset, the cycle can repeat for the next photon detection event.

The graph in FIG. 2C provides a clear visualization of the voltage changes occurring at the SPAD cathode during the avalanche event and the subsequent quenching and reset phases. This voltage waveform demonstrates the effective operation of the passive and active quenching circuits in controlling the SPAD's behavior, enabling quick quenching with a reduction of the charge per pulse (CPP), the charge flowing through the SPAD during the avalanche. The active path assists in discharging the cathode voltage, effectively diverting some current from the SPAD during the avalanche, which contributes to the reduction in CPP.

The use of the negative voltage VSSNEG in the active quenching circuit provides several benefits. First, VSSNEG helps to discharge the cathode voltage more quickly during the active quenching phase, reducing the overall quenching time. This faster quenching is achieved by M3 pulling the SPAD cathode to VSSNEG, as shown in FIG. 2D. The reduced quenching time allows for a higher maximum count rate, as the SPAD can be quenched and ready for the passive reset phase more quickly.

Furthermore, the application of VSSNEG reduces the charge flow through the high-voltage node (NegV) and the SPAD itself during the avalanche event. This reduced charge flow minimizes afterpulsing, which is a common issue in SPADs where trapped charges from a previous avalanche event can trigger false detection events. By reducing the occurrence of afterpulsing, the performance and reliability of the SPAD are improved.

Overall therefore, the incorporation of the active quenching circuit with the negative voltage VSSNEG, along with the passive quenching circuit, helps optimize SPAD operation by reducing quenching time, reducing charge flow, and mitigating afterpulsing effects. These enhancements lead to improved energy per pulse, higher maximum count rates, and better overall performance of the SPAD-based single-photon detector.

### B. Active Reset

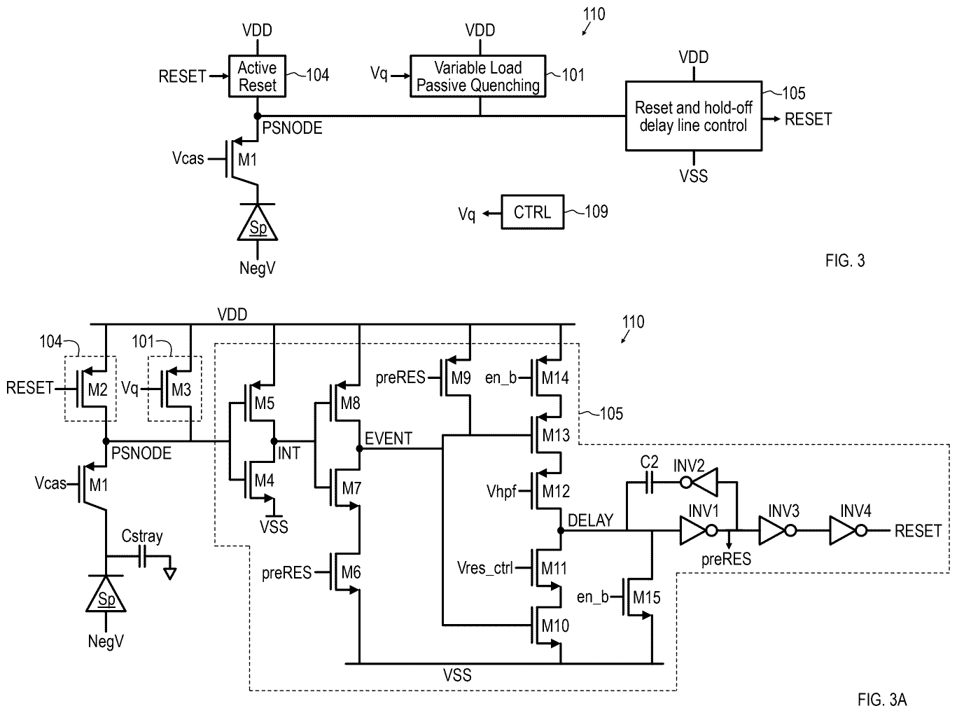

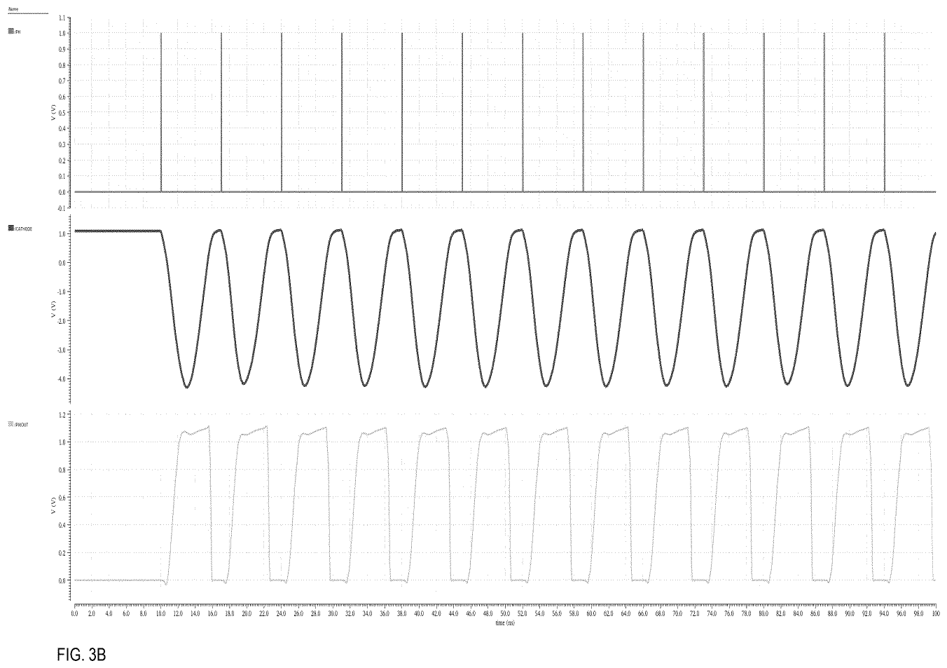

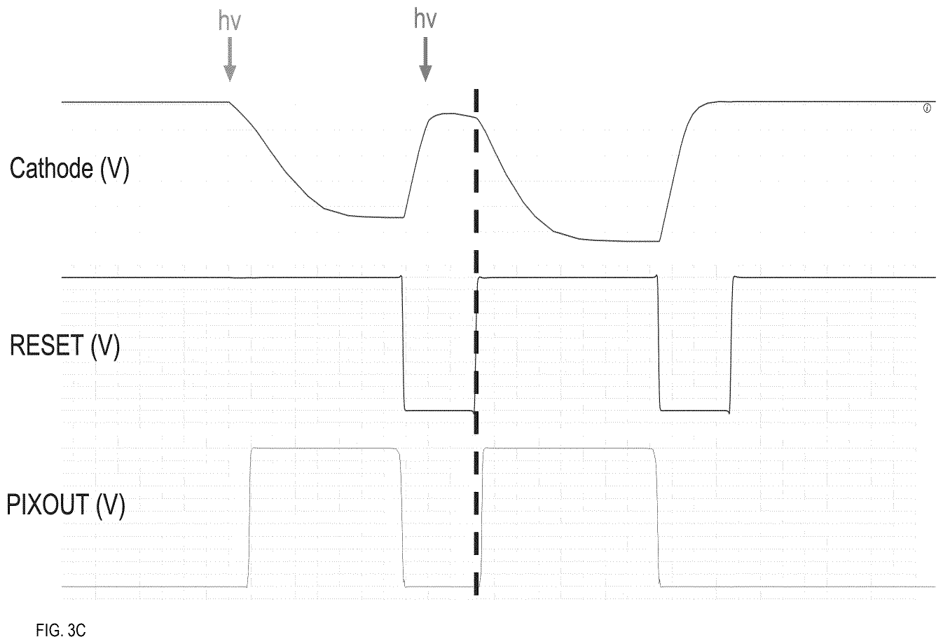

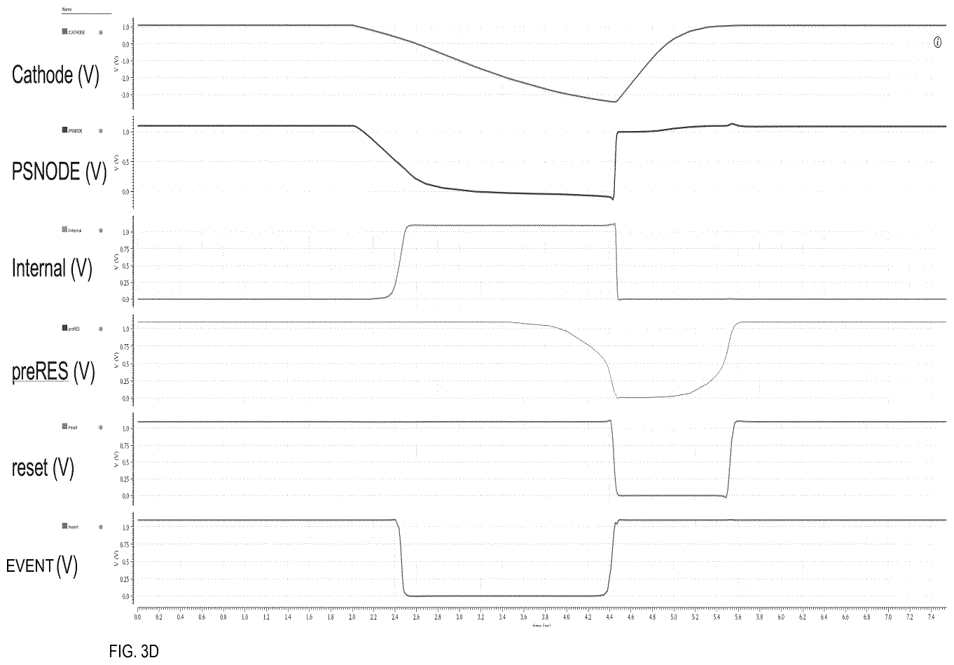

Now described with reference to FIG. 3 is a SPAD pixel 110, which includes a SPAD Sp, which may be a fully depleted three dimensional SPAD, having its anode directly connected to a high negative voltage NegV, and having its cathode coupled to a supply voltage VDD through a cascode transistor M1 and a passive quenching circuit 101 as well as an active reset circuit 104. The cathode of the SPAD Sp is read at a node labelled PSNODE at the source of the cascode transistor M1.

The passive quenching circuit 101 serves to limit the current flow through the SPAD Sp during an avalanche event, helping to quench the avalanche. Readout and delay generation circuitry 105, powered between the supply voltage VDD and a reference voltage VSS, performs this readout of node PSNODE.

The active reset circuit 104 provides a rapid reset mechanism for the SPAD after an avalanche event, allowing the SPAD to recover quickly and be ready for the next detection event.

Further details are shown in FIG. 3A. The cascode transistor M1, an extended-drain PMOS capable of handling a drain-to-source voltage of 5 to 7 volts or higher, has its drain connected to the cathode of SPAD Sp, its source connected to node PSNODE, and its gate controlled by a cascode control signal Vcas.

The passive quenching circuit 101 is formed by a PMOS transistor M3 having its source connected to the supply voltage VDD, its drain connected to PSNODE, and its gate controlled by a quench control signal Vq generated by control circuitry 109 or externally provided to control the quenching resistance.

The active reset circuit 104 is formed by an PMOS transistor M2 having its drain connected to PSNODE, its source connected to the voltage VDD, and its gate controlled by a reset signal RESET generated by readout circuit 105.

The readout circuitry 105 includes an inverter formed by PMOS M5 and NMOS M4 series connected between the supply voltage VDD and the reference voltage VSS. The input of the inverter is connected to PSNODE, and the output of the inverter is connected to node INT. PMOS M5 has its source connected to the supply voltage VDD, its drain connected to node INT, and its gate controlled by the voltage at PSNODE. NMOS M4 has its drain connected to node INT, its source connected to the reference voltage VSS, and its gate controlled by the voltage at PSNODE.

Another inverter is formed by PMOS M8 and NMOS M7 series connected between the supply voltage VDD and NMOS M6. PMOS M8 has its source connected to the supply voltage VDD, its drain connected to node EVENT, and its gate controlled by the voltage at INT. NMOS M7 has its drain connected to node EVENT, its source connected to the drain of NMOS M6, and its gate controlled by the voltage at INT. NMOS M6 has its drain connected to the source of NMOS M7, its source connected to the reference voltage VSS, and its gate controlled by a voltage preRES, a switchingable signal coming from the output of INV1.

PMOS transistor M9 has its source connected to supply voltage VDD, its drain connected to node EVENT, and its gate controlled by the voltage preRES. PMOS transistor M14 has its source connected to the supply voltage VDD, its drain connected to the source of PMOS transistor M13, and its gate controlled by the complement en_b of an enable signal en. PMOS transistor M13 has its source connected to the drain of PMOS transistor M14, its drain connected to the source of PMOS transistor M12, and its gate connected to node EVENT. PMOS transistor M12 has its source connected to the drain of PMOS transistor M13, its drain connected to node DELAY, and its gate controlled by signal Vhpf. NMOS transistor M11 has its drain connected to node DELAY, its source connected to the drain of NMOS transistor M10, and its gate controlled by signal Vres_ctrl. NMOS transistor M10 has its drain connected to the source of NMOS transistor M11, its source connected to the reference voltage VSS, and its gate connected to node EVENT. NMOS transistor M15 has its drain connected to node DELAY, its source connected to reference voltage VSS, and its gate controlled by en_b. Three inverters, INV1, INV3, and INV4, are series connected between nodes DELAY and RESET. An inverter INV2 has its input connected to the output of inverter INV1 and its output coupled to node DELAY through capacitor C2.

FIG. 3B illustrates the operation of the SPAD pixel with passive quenching and active reset at high count rates. The timing diagram shows the photon strikes, cathode voltage, and output signal waveforms when multiple photons are detected in rapid succession, demonstrating the pixel's ability to efficiently handle high photon flux.

When a photon is detected by the SPAD Sp, an avalanche event occurs, causing a sudden drop in the voltage at the SPAD cathode, as shown in the graph of FIG. 3D. This voltage drop is sensed at node PSNODE, which is buffered by the cascode transistor M1. The graph of FIG. 3D shows the corresponding voltage drop at PSNODE. The passive quenching circuit 101, formed by PMOS transistor M3, limits the current through the SPAD during the avalanche event, helping to quench the avalanche.

The readout circuitry 105 detects the voltage change at PSNODE and generates a digital pulse at node INT, as shown in the graph of FIG. 3D. This pulse is then inverted by the inverter formed by PMOS M8 and NMOS M7, creating a pulse at node EVENT, as depicted in the graph of FIG. 3D. The pulse at node EVENT is gated by NMOS transistor M6, which is controlled by the voltage preRES. This allows for the pulse to be selectively passed to the delay generation circuit 105.

The delay generation circuit 105 generates a delayed version of the EVENT pulse at node DELAY. The graph in FIG. 3D shows the output pulse generated by the pixel, which is a result of the delayed EVENT pulse propagating through the inverter chain.

The delayed pulse is then inverted by the series-connected inverters INV1, INV3, and INV4 to create the RESET signal, as shown in the graph of FIG. 3D. The RESET signal is fed back to the active reset circuit 104, formed by PMOS transistor M2, which quickly resets the SPAD by pulling PSNODE and CATHODE to the voltage VDD. This rapid reset operation is evident in the FIG. 3D, where the voltages quickly return to their initial levels after the reset pulse.

The enable signal en and its complement en_b control the operation of the delay generation circuit through transistors M14 and M15. When en is high (and en_b is low), the delay generation circuit is enabled, allowing the RESET signal to be generated. When en is low (and en_b is high), the delay generation circuit is disabled, preventing the generation of the RESET signal.

The timing diagram in FIG. 3C illustrates the overall operation of the SPAD pixel. The “hv” arrow indicates the incident photon, which triggers the avalanche event. The cathode voltage trace shows the sharp voltage drop during the avalanche, followed by the reset operation. The reset voltage RESET trace depicts the generated reset pulse, which is used to reset the SPAD. The output signal PIXOUT trace represents the output pulse generated by the pixel, indicating the detection of a photon. Also illustrated in FIG. 3C is the guaranteed reset operation of the SPAD pixel even when a photon hits the detector during the reset time (the second arrow labeled as “hv” indicates this photon strike).

The combination of the passive quenching circuit 101 and the active reset circuit 104, along with the readout circuitry and delay generation circuit 105, enables efficient avalanche quenching and precise control of the hold-off and reset phases. This allows for improved SPAD performance, including increased maximum count rate, reduction of reset time and dead time, and better control of the reset timing compared to passive quenching alone.

### C. Active Quenching and Active Reset

The active quenching of the SPAD pixel 100 of FIG. 2 may be combined with the active reset of the SPAD pixel 110 of FIG. 3.

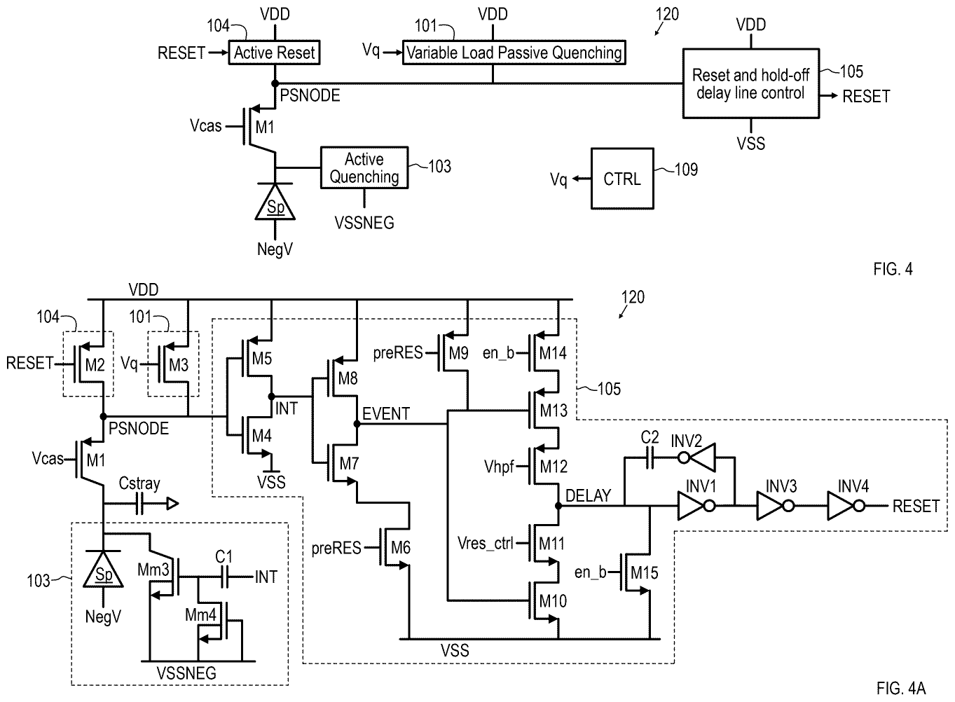

Now described with reference to FIG. 4 is a SPAD pixel 120, which includes a SPAD Sp, which may be a fully depleted three dimensional SPAD, having its anode directly connected to a high negative voltage NegV, and having its cathode coupled to a supply voltage VDD through a cascode transistor M1 and a variable load passive quenching circuit 101 as well as an active reset circuit 104. The cathode of the SPAD Sp is read at a node labelled PSNODE at the source of the cascode transistor M1. A passive quenching circuit 101 serves to limit the current flow through the SPAD Sp during an avalanche event, helping to quench the avalanche. An active quenching circuit 103 is connected to the drain of cascode transistor M1 and performs active quenching of the SPAD Sp, utilizing a negative voltage VSSNEG. A readout circuitry and delay generation circuit 105, powered between the supply voltage VDD and a reference voltage VSS, generates a reset signal and controls the hold-off delay for the SPAD pixel. The active reset circuit 104 provides a rapid reset mechanism for the SPAD after an avalanche event, allowing the SPAD to recover quickly and be ready for the next detection event.

Further details are shown in FIG. 4A. The cascode transistor M1, an extended-drain PMOS capable of handling a drain-to-source voltage of 5 to 7 volts or higher, has its drain connected to the cathode of SPAD Sp, its source connected to node PSNODE, and its gate controlled by a cascode control signal Vcas.

The passive quenching circuit 101 is formed by a PMOS transistor M3 having its source connected to the supply voltage VDD, its drain connected to PSNODE, and its gate controlled by a quench control signal Vq generated by control circuitry 109 or externally provided to control the quenching resistance.

The active reset circuit 104 is formed by an PMOS transistor M2 having its drain connected to PSNODE, its source connected to the voltage VDD, and its gate controlled by a reset signal RESET.

A capacitor Cstray represents the stray capacitance associated with the cathode of SPAD Sp and is illustrated as being coupled between the cathode of SPAD Sp and ground.

The active quenching circuit 103 includes an extended-drain NMOS transistor Mm3 having its drain connected to the cathode of SPAD Sp, its source and body connected to the negative voltage VSSNEG, and its gate coupled through capacitor C1 to node INT. An NMOS transistor Mm4 has its drain connected to the gate of Mm3, and its source, body, and gate connected to the negative voltage VSSNEG.

The readout circuitry 105 includes an inverter formed by PMOS M5 and NMOS M4 series connected between the supply voltage VDD and the reference voltage VSS. The input of the inverter is connected to PSNODE, and the output of the inverter is connected to node INT. PMOS M5 has its source connected to the supply voltage VDD, its drain connected to node INT, and its gate controlled by the voltage at PSNODE. NMOS M4 has its drain connected to node INT, its source connected to the reference voltage VSS, and its gate controlled by the voltage at PSNODE.

Another inverter is formed by PMOS M8 and NMOS M7 series connected between the supply voltage VDD and NMOS M6. PMOS M8 has its source connected to the supply voltage VDD, its drain connected to node EVENT, and its gate controlled by the voltage at INT. NMOS M7 has its drain connected to node EVENT, its source connected to the drain of NMOS M6, and its gate controlled by the voltage at INT. NMOS M6 has its drain connected to the source of NMOS M7, its source connected to the reference voltage VSS, and its gate controlled by a voltage preRES.

PMOS transistor M9 has its source connected to supply voltage VDD, its drain connected to node EVENT, and its gate controlled by voltage preRES. PMOS transistor M14 has its source connected to the supply voltage VDD, its drain connected to the source of PMOS transistor M13, and its gate controlled by the complement en_b of an enable signal en. PMOS transistor M13 has its source connected to the drain of PMOS transistor M14, its drain connected to the source of PMOS transistor M12, and its gate connected to node EVENT. PMOS transistor M12 has its source connected to the drain of PMOS transistor M13, its drain connected to node DELAY, and its gate controlled by signal Vhpf. NMOS transistor M11 has its drain connected to node DELAY, its source connected to the drain of NMOS transistor M10, and its gate controlled by signal Vres_ctrl. NMOS transistor M10 has its drain connected to the source of NMOS transistor M11, its source connected to the reference voltage VSS, and its gate connected to node EVENT. NMOS transistor M15 has its drain connected to node DELAY, its source connected to reference voltage VSS, and its gate controlled by en_b. Three inverters, INV1, INV3, and INV4, are series connected between nodes DELAY and RESET. An inverter INV2 has its input connected to the output of inverter INV1 and its output coupled to node DELAY through capacitor C2.

When a photon is detected by the SPAD Sp, an avalanche event occurs, causing a sudden drop in the voltage at the cathode of the SPAD Sp. This voltage drop is sensed at node PSNODE, which is buffered by the cascode transistor M1. The passive quenching circuit 101, formed by PMOS transistor M3, limits the current through the SPAD during the avalanche event, helping to quench the avalanche.

The active quenching circuit 103 detects the onset of the avalanche through the coupling of node INT to the gate of transistor Mm3 via capacitor C1. Transistor Mm3 quickly pulls the SPAD cathode to the negative voltage VSSNEG, rapidly quenching the avalanche and enabling faster reset of the SPAD. Transistor Mm4 acts as a weak pull-down to prevent the gate of Mm3 from floating during the reset phase.

The readout circuitry 105 detects the voltage change at PSNODE and generates a digital pulse at node INT. The inverter formed by M5 and M4 inverts the pulse at node INT. The pulse is then inverted again by the inverter formed by M8 and M7, creating a pulse at node EVENT. The pulse at node EVENT is gated by NMOS transistor M6, which is controlled by the voltage preRES. This allows for the pulse to be selectively passed to the delay generation circuit.

The delay generation circuit 105 generates a delayed version of the EVENT pulse at node DELAY. Inverter INV2 and capacitor C2 help to shape the DELAY signal. The delayed pulse is then inverted by the series-connected inverters INV1, INV3, and INV4 to create the RESET signal.

The RESET signal is fed back to the active reset circuit, formed by transistor M2, which quickly resets the SPAD by pulling PSNODE and CATHODE to the voltage VDD. This rapid reset operation allows the SPAD to recover quickly and be ready for the next detection event.

The enable signal en and its complement en_b control the operation of the delay generation circuit through transistors M14 and M15. When en is high (and en_b is low), the delay generation circuit is enabled, allowing the RESET signal to be generated. When en is low (and en_b is high), the delay generation circuit is disabled, preventing the generation of the RESET signal.

The combination of the passive quenching circuit 101, active quenching circuit 103, and readout circuitry and delay generation circuit 105 enables efficient avalanche quenching, rapid SPAD reset, and precise control of the reset timing. This allows for improved SPAD performance, higher count rates, and reduced afterpulsing effects, and a reduction in the energy per pulse compared to passive quenching alone. The adjustable hold-off delay provided by the delay generation circuit further enhances the SPAD performance by allowing for customization of the dead time between detection events.

Finally, it is evident that modifications and variations can be made to what has been described and illustrated herein without departing from the scope of this disclosure.

Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

1. A single photon avalanche diode (SPAD) pixel circuit, comprising:
a SPAD having an anode coupled to a negative voltage and a cathode;
a cascode transistor having a drain coupled to the cathode of the SPAD, a gate controlled by a cascode control signal, and a source;
readout circuit coupled to the source of the cascode transistor and configured to detect a voltage change at the source of the cascode transistor and generate a pulse indicating an occurrence of an avalanche event; and
an active quenching circuit coupled to the cathode of the SPAD and configured to detect an onset of the avalanche event and pull the cathode of the SPAD to a negative voltage to quench the avalanche event.

2. The SPAD pixel circuit of claim 1, wherein the cascode transistor is an extended-drain PMOS transistor.

3. The SPAD pixel circuit of claim 1, further comprising a passive quenching circuit coupled to the source of the cascode transistor; and wherein the passive quenching circuit comprises a PMOS transistor having a source coupled to a supply voltage, a drain coupled to the source of the cascode transistor, and a gate controlled by a quench control signal.

4. The SPAD pixel circuit of claim 1, wherein the readout circuit comprises:
an inverter having an input coupled to the source of the cascode transistor and an output; and
a delay circuit coupled to the output of the inverter and configured to extend a duration of the pulse.

5. The SPAD pixel circuit of claim 1, wherein the active quenching circuit comprises:
a first NMOS transistor having a drain coupled to the cathode of the SPAD, a source and a body coupled to the negative voltage, and a gate; and
a capacitor coupled between the gate of the first NMOS transistor and an output of the readout circuit.

6. The SPAD pixel circuit of claim 5, wherein the active quenching circuit further comprises a second NMOS transistor having a drain coupled to the gate of the first NMOS transistor, and a source, a body, and a gate coupled to the negative voltage.

7. The SPAD pixel circuit of claim 1, wherein the SPAD is a fully depleted three-dimensional SPAD.

8. The SPAD pixel circuit of claim 1, wherein the negative voltage is lower than a reference voltage coupled to the readout circuit.

9. A single photon avalanche diode (SPAD) pixel circuit, comprising:
a SPAD having an anode coupled to a negative voltage and a cathode;
a cascode transistor having a drain coupled to the cathode of the SPAD, a source coupled to an active reset circuit, and a gate controlled by a cascode control signal; and
a readout circuit coupled to the source of the cascode transistor and configured to detect a voltage change at the source of the cascode transistor and generate a digital pulse indicating an occurrence of an avalanche event;
wherein the active reset circuit is coupled to the source of the cascode transistor and configured to reset the SPAD after the avalanche event by pulling the source of the cascode transistor to a reference voltage.

10. The SPAD pixel circuit of claim 9, wherein the cascode transistor is an extended-drain PMOS transistor.

11. The SPAD pixel circuit of claim 9, further comprising a passive quenching circuit coupled to the source of the cascode transistor; and wherein the passive quenching circuit comprises a PMOS transistor having a source coupled to a supply voltage, a drain coupled to the source of the cascode transistor, and a gate controlled by a quench control signal.

12. The SPAD pixel circuit of claim 9, wherein the active reset circuit comprises an PMOS transistor having a drain coupled to the source of the cascode transistor, a source coupled to the reference voltage, and a gate controlled by a reset signal.

13. The SPAD pixel circuit of claim 12, further comprising a delay generation circuit coupled to the readout circuit and configured to generate a delayed version of the digital pulse and provide the delayed version as the reset signal to the active reset circuit.

14. The SPAD pixel circuit of claim 13, wherein the delay generation circuit comprises:
a series of inverters coupled between an output of the readout circuit and the reset signal; and
a capacitor coupled between an output of a first inverter in the series of inverters and an input of a second inverter in the series of inverters.

15. The SPAD pixel circuit of claim 13, wherein the delay generation circuit is controlled by an enable signal and its complement.

16. The SPAD pixel circuit of claim 13, wherein the readout circuit comprises:
a first inverter having an input coupled to the source of the cascode transistor and an output; and
a second inverter having an input coupled to the output of the first inverter and an output coupled to the delay generation circuit.

17. The SPAD pixel circuit of claim 16, wherein the second inverter comprises:
a PMOS transistor and an NMOS transistor coupled in series between a supply voltage and a gated NMOS transistor, the gated NMOS transistor having a gate controlled by a control voltage.

18. The SPAD pixel circuit of claim 9, wherein the SPAD is a fully depleted three-dimensional SPAD.

19. A method of operating a single photon avalanche diode (SPAD) pixel, the method comprising:
passively quenching an avalanche event in a SPAD by limiting current flow through the SPAD using a passive quenching circuit;
actively quenching the avalanche event by pulling a cathode of the SPAD to a negative voltage using an active quenching circuit;
detecting the avalanche event at the cathode of the SPAD using a readout circuit; and
generating an output pulse with the readout circuit in response to detecting the avalanche event.

20. The method of claim 19,
wherein detecting the avalanche event comprises: inverting a voltage change at the cathode of the SPAD using an inverter in the readout circuit; and generating a pulse at an output of the inverter in response to the voltage change; and
further comprising: extending a duration of the pulse using a delay circuit in the readout circuit; and using the extended pulse to control a transistor connected to the output of the inverter.
